(19) United States
(12) Patent Application Publication
(10) Pub. No.: US 2006/0220251 A1
(43) Pub. Date: Oct. 5, 2006

(54) Reducing internal film stress in dielectric film

(76) Inventors: Grant Kloster, Lake Oswego, OR (US); Boyan Boyanov, Portland, OR (US); Michael Goodner, Hillsboro, OR (US); Mansour Moinpour, San Jose, CA (US); Michael Haverty, Mountain View, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/096,678

(22) Filed: Mar. 31, 2005

(51) Int. Cl. H01L 23/48

(52) U.S. Cl. 257/758

(57) ABSTRACT

A method of forming a film. The method comprises depositing a porous film. The porous film has active end groups; and preventing cross-linking among said active end groups, wherein the end groups are capped with less reactive or unreactive groups.

### FIELD

Embodiments of the present invention relate to the field of fabricating microelectronic devices. More particularly, embodiments of the present invention relate to decreasing/reducing internal film stress in a porous dielectric film.

### BACKGROUND

Modern integrated circuits generally contain several layers of interconnect structures fabricated above a substrate. The substrate may have active devices and/or conductors that are connected by the interconnect structures.

Interconnect structures, typically comprising trenches and vias, are usually fabricated in, or on, an interlayer dielectric (ILD). It is generally accepted that, the dielectric material in each ILD should have a low dielectric constant (K) to obtain low capacitance between conductors. Decreasing this capacitance between conductors, by using a low dielectric constant K results in several advantages. For instance, it provides reduced RC delay, reduced power dissipation, and reduced cross-talk between the metal lines. Currently, components in the dielectric material are replaced by air to significantly reduce the dielectric constant. For instance, many dielectric materials comprise silicon dioxide; and replacing some of the silicon dioxide with air to create pores in the ILD reduces the dielectric constant. Many dielectric materials are currently being formed with solid dielectric materials having pores therein. The degree of porosity generally relates to a reduction in bond strength (compared to a solid dielectric layer of a similar composition) because of reduced contact area.

To obtain the desired low dielectric constant, porosity is often introduced into the dielectric material. These pores typically increase problems that inherently exist when further processing is done on dielectric material. One problem with having too many pores in the ILD is that the mechanical structure of the ILD is weaker or more fragile due to the porosity. Thus, cracking is prone to happen. Another problem is that the surface of the ILD is more fragile and more prone to surface breakage. Even slight breakage may be problematic in microcircuit applications, such as device failure and contaminations.

### BRIEF DESCRIPTION OF THE DRAWINGS

The embodiments of the present invention are illustrated by way of example and not by way of limitation in the figures of the accompanying drawings in which like references indicate similar elements. The invention may best be understood by referring to the following description and accompanying drawings that are used to illustrate embodiments of the invention. It should be noted that references to “an” or “one” embodiment of the invention in this disclosure are not necessarily to the same embodiment, and they mean at least one. In the drawings:

FIG. 1 illustrates an example of a porous dielectric film with active end groups;

FIG. 2 illustrates an example of the porous dielectric film in FIG. 1 being hydrolyzed;

FIG. 3 illustrates an example of the porous dielectric film in FIG. 2 having the active end groups cross-linking to one another increasing internal stress of the film;

FIGS. 4-5 illustrate various dielectric films after being cured and experiencing internal stress increase;

FIG. 6 illustrates an exemplary a porous dielectric film with active end groups;

FIG. 7 illustrates the porous dielectric film in FIG. 6 being hydrolyzed;

FIG. 8 illustrates the porous dielectric film in FIG. 7 having the active end groups capped with unreactive end groups preventing cross-linking;

FIGS. 9A-B illustrate exemplary embodiments of microelectronic devices having porous dielectric films formed in accordance to embodiments of the present invention;

FIG. 10 illustrates an exemplary method of forming a porous film with active end groups being capped by unreactive end groups; and

FIG. 11 illustrates another exemplary method of forming a porous film with active end groups being capped by unreactive end groups.

### DETAILED DESCRIPTION

Exemplary embodiments are described with reference to specific configurations and techniques. Those of ordinary skill in the art will appreciate the various changes and modifications to be made while remaining within the scope of the appended claims. Additionally, well known elements, devices, components, circuits, process steps and the like are not set forth in detail.

When a dielectric film is made to have a low dielectric constant (K), pores or voids are often formed into the dielectric material during the deposition process of the dielectric film. Air is often used to replace solid dielectric material to reduce the dielectric constant. Often, a pore-forming agent is co-deposited with the precursors that are used to deposit the dielectric film. The pore-forming agent is then decomposed (e.g., via curing) to create voids, pores, or air gaps in the dielectric film. The porosity in the dielectric film weakens the mechanical structure of the dielectric film since structural supports within the film are removed as pores are generated. Additionally, when the pores are formed in the dielectric film, active end groups, also known as “dangling groups” or “dangling bonds” are also generated. For instance, when the dielectric film is made of silicon dioxide, the active end groups Si—H and Si—OH are often formed as the dangling groups. These active end groups tend to react among each other and cause cross-linking between among the groups. The cross-linking may lead to film shrinkage, which results in increased internal tensile stress of the porous dielectric film. The increase in internal tensile stress makes the dielectric film more prone or predisposed to cracking and breaking when the dielectric film is subjected to normal impact of subsequent processing. For instance, weak mechanical strength in the dielectric film leads to cracking during standard microelectronic processing steps such as chemical mechanical polishing and packaging.

The active end groups tend to react among each other when the dielectric film is subjected to subsequent curing processes. A curing process is typically needed to decompose the pore-forming agent co-deposited in the film in order to generate the pores. Embodiments of the present invention pertain to capping the active end groups in the porous dielectric film with unreactive groups that are not “leaving groups” so that the unreactive end groups prevents cross-linking among the active end groups in the dielectric film. When cross-linking is reduced, the tensile stress within the dielectric film is reduced and the cohesive strength of the dielectric film increases. This results in a highly porous dielectric film with low stress. Cracking in the film typically caused by subsequent impact is thus reduced.

Additionally, the porous dielectric film made in according to embodiments of the present invention is also able to withstand or be used in lead-free packaging without the concern of the film being predisposed to cracking and breaking. In some applications, packaging of devices is achieved using a lead-free component such as copper or other metal as opposed to using lead. However, when a lead-free component is used, more stress is imposed upon a dielectric film. Thus, being able to lower the internal stress in a highly porous dielectric film (low K) is advantageous since it makes the dielectric film less predisposed or prone to cracking and breaking.

Additionally, the porous dielectric film made in according to embodiments of the present invention is also able to withstand more vigorous processing such as Chemical Mechanical Polishing, which is typically used in a dual damascene processing to make interconnections for a microelectronic device.

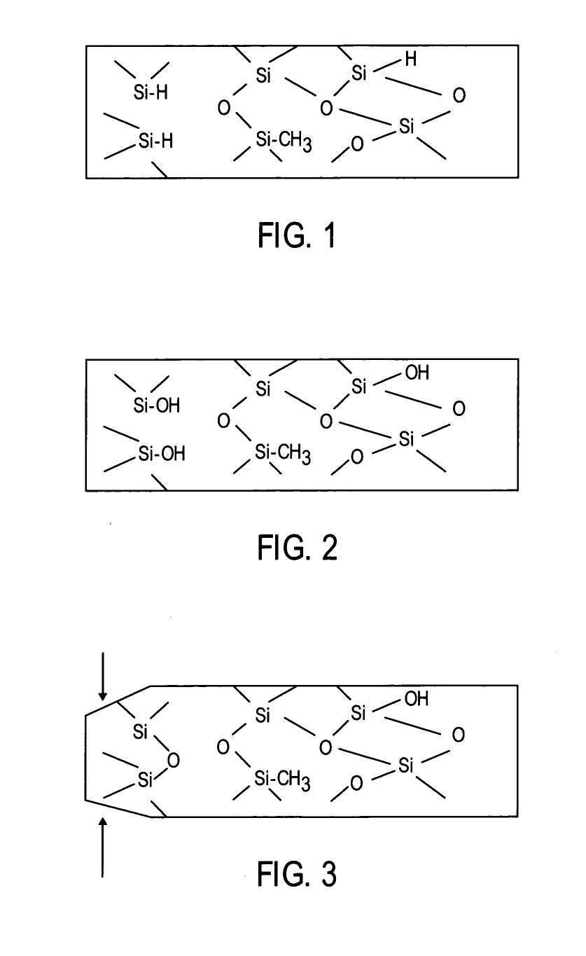

FIGS. 1-3 illustrate an example of a porous dielectric film formed using a conventional method that suffers from easy cracking and breaking. The dielectric film in this example includes silicon dioxide. It is to be noted that other porous dielectric film experience similar problems and not just dielectric film that includes silicon dioxide. In FIG. 1, after the porous dielectric film is formed, active end groups are exposed. The active end groups include Si—H and/or Si—OH. For instance, as shown in FIG. 2, some Si—H groups may be hydrolyzed (via moisture in the ambient) to form Si—OH. Also, Si—H bonds are known to be quite labile which makes the Si—H bonds to break off easily to form other molecules and in this case, easily form Si—OH molecules. Neighboring Si—OH bonds can then cross-link one to another, releasing water molecule and form Si—O—Si as shown in FIG. 3. Such cross-linking pulls the film together, reduces the film thickness, and consequently increases the internal film stress. During subsequent processing, when the film is subject to normal impact, the film is more prone to cracking and breaking.

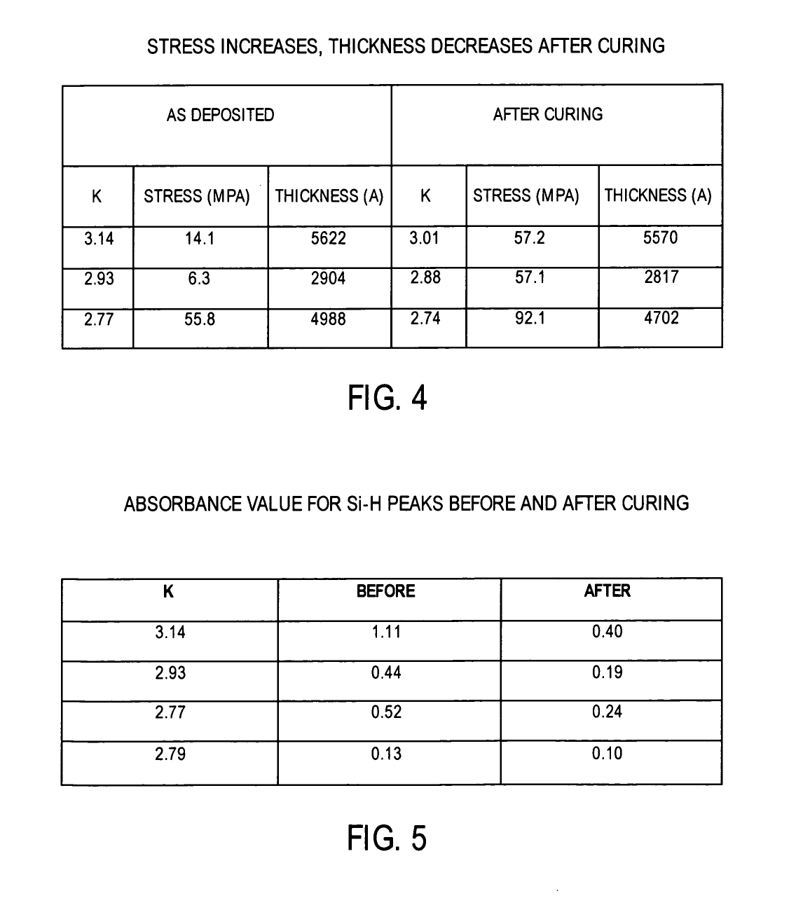

FIGS. 4-5 illustrate some data representative of stress increase, thickness decrease, and cross-linking in a conventionally formed porous dielectric film (e.g., silicon dioxide). In FIG. 4, a porous dielectric film is formed using a conventional process (e.g., deposit the dielectric film with a pore-forming agent and decompose the pore-forming agent by curing to form pores in the dielectric film). In the figures, “K” indicates the dielectric constant for a particular film. “Stress” indicates a measured unit of internal stress of the film in Mega Pascal (MPA) for the particular film using a conventional measuring technique. “Thickness” indicates the thickness of the film in Angstrom (A). “As Deposited” indicates the film after being formed but before curing; and “After Curing” indicates the film after curing or heating so as to decompose the pore-forming agents to create pores in the dielectric film. In one example, a film with a dielectric constant K of 3.14 has an internal stress value of 14.1 after being deposited but has a several fold increased stress value of 57.2 after being cured. Similarly, another film with a dielectric constant K of 2.93 has an internal stress value of 6.3 after being deposited but has a several fold increased stress value of 57.1 after being cured. FIG. 4 thus indicates that after curing a particular dielectric film formed using a conventional method, the film stress increases and thickness decreases.

In FIG. 5 illustrates further that cross-linking takes place as a result of curing the dielectric film. FIG. 5 illustrates that, in one example, the amount of Si—H bonds decreases after curing by analyzing the absorbance values for Si—H peaks in a particular film. The decrease in Si—H bonds tends to indicate that the Si—H bonds break off and allowing Si—OH to form. Bonding or cross-linking among Si—OH bonds then occurs to form Si—O—Si. As discussed above, the cross-linking of the Si—OH bonds causes shrinking in the film and internal stress increase in the film. As shown in FIG. 5, in one example, for a film with a K 3.14, the Si—H bond value (measured by Si—H peaks using a conventional technique such as FTIR, NMR, and X-Rays) is at 1.11. However, after curing, the Si—H bond value decreases to 0.40. Similar decreases can be seen for other films shown in FIG. 5.

In according to embodiments of the present invention, active end groups in a dielectric film are capped with less reactive or unreactive end groups so that cross-linking among active end groups are minimized. Less reactive or unreactive end groups refer to moieties that once bonded to a molecule do not tend to leave and break off easily as compared to active end groups such as —H or —OH bonded to active Si. In one embodiment, a porous dielectric film is formed by first having the precursors for the film being co-deposited with one or more pore-forming agents. During a curing process to decompose the pore-forming agents to form pores in the dielectric film, active end groups (e.g., Si—H and/or Si—OH) are blocked by less reactive or unreactive end groups. To block the active end groups, immediately after curing or before curing, and after the dielectric film is deposited, the dielectric film is treated with one or more end-capping reagents before the active end groups are allowed to cross-link to one another. Blocking the active end groups allows the dielectric film to be stabilized and be cured with reduced or no cross-linking that will cause shrinkage or increase in internal film stress to the dielectric film.

The end-capping reagents that can be used include Hexamethyldisiazane (HMDS), R₃Si(OCH₃), (CH₃)₃Si(OCH₃), R₃SiCl, (CH₃)₃SiCl, R₃OH, CH₃OH, R₃Cl, CH₃Cl, or CH₄. In some embodiments, vapor treatment is used to expose the dielectric film to the end-capping reagents. In some embodiments, plasma treatment is used expose the dielectric film to the end-capping reagents or to activate the capping reaction. For instance, end-capping reagents similar to R₃OH, CH₃OH, R₃Cl, CH₃Cl, or CH₄ may be more difficult to break or react to other groups. The bonds of these molecules can be broken by plasma or other energy source to allow them to bond to or cap the active end groups in the dielectric film. When activated by plasma or other energy source, the reagents such as R₃OH, CH₃OH, R₃Cl, CH₃Cl, or CH₄ form radical species that can bond to the active end groups in the dielectric film.

Other end-capping reagents can also be used. Typical characteristics of the end-capping reagents include: (1) the end-capping reagent contains molecules that are not so reactive to allow the molecules to act as blocking molecules for the active end groups in the dielectric film; (2) the end-capping reagent contains molecules that are small enough to penetrate the entire dielectric film or the bulk of the dielectric film; and (3) the end-capping reagent contains molecules that do not cause an increase in the dielectric constant value of the dielectric film or do not cause an impact of the dielectric constant value of the dielectric film.

There are several possible ways of treating a porous dielectric film with the end-capping reagent to block the active end groups in the dielectric film. In one embodiment, the dielectric film is treated with the end-capping reagent before a curing process such as curing that is used to decompose the pore-forming agent. Treating the film with the end-capping reagent mitigate cross-linking among active end groups, for example, by removing Si—H or Si—OH end groups. In another embodiment, the dielectric film is treated with the end-capping reagent between a deposition and curing process. In another embodiment, the dielectric film is treated with the end-capping reagent during a curing process. In another embodiment, the dielectric film is treated with the end-capping reagent immediately after a curing process. Treating the dielectric film with the end-capping reagent after curing may be applied to prevent slow hydrolysis and/or cross-linking of the active end groups.

In any event, the end-capping reagent treatment must occur before cross-linking among the active end groups takes place in the dielectric film. Typically, cross-linking among the active end groups occur when the dielectric film is cured since this process causes the pores as well as the dangling bonds or the active end groups to form.

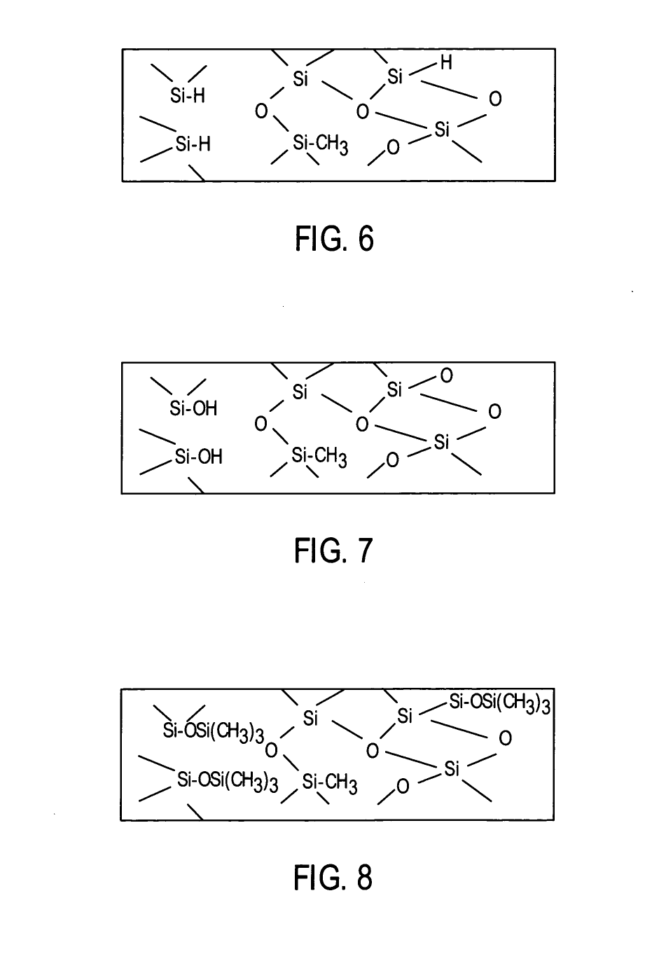

FIG. 6 illustrates a dielectric film being formed in according to embodiments of the present invention. Precursors for the dielectric film and pore-forming agents are co-deposited using a conventional method. The dielectric film may also be doped with carbon groups such as methyl groups. The deposition may take place in a deposition device/chamber typically used for Chemical Vapor Deposition, Physical Vapor Deposition, Plasma Enhanced Chemical Vapor Deposition, or Spin on deposition. The dielectric film may be formed using conventional operating temperatures and pressures. The dielectric film may have a thickness between approximately 100 Angstroms to approximately 10,000 Angstroms.

Examples of precursors that can be used to deposit the dielectric film includes, but are not limited to, tetraethylorthosilicate (TEOS); tetramethylcyclotetrasiloxane (TMCTS) or trade name of J. C. Schumacher, a unit of Air Products and Chemicals, Inc, (TOMCATS); dimenthyldimethoxysilane (DMDMOS); octamethylcyclotetrasiloxane (OMCTS); tetramethoxysilane (TMOS); diacetoxyditertiarybutoxysilane (DADBS). The dielectric film can also be formed in the presence of carbon so that the dielectric film is carbon doped using methods known in the art. The precursors are typically silane-based precursors. The precursors can have the form of polymers or oligomers.

Example of pore-forming agents include PLC (hyperbranched poly(caprolactone)) with hydroxyl end groups, PEO-b-PPO-PEO (triblock copolymer, poly(ethylene oxide-b-propylene oxide-b-ethylene oxide), copolymers of PEO (poly(ethylene oxide)) and copolymers of PPO ((poly(propylene oxide)), or the like. Pore-forming agents are generally sacrificial nanoparticles or “porogens” that are desorbed during film curing to leave pores or voids in the dielectric film. Many pore-forming agents are known in the art.

FIG. 7 illustrates the dielectric film after deposition where some Si—H molecules hydrolyze to form Si—OH due to exposure to moisture of the ambient. If left untreated, the active and groups Si—H and Si—OH cross-link among one another to cause shrinking in the dielectric film as previously described. In one embodiment, the dielectric film is treated with an end capping reagents so that the active end groups are blocked from cross-linking to one another. The end-capping reagent provides less reactive or unreactive molecules that will react or bond to the active end groups and thus blocking the active end groups. In one embodiment, an end-capping reagent is used to treat the dielectric film such that the Si—OH and the Si—H active end groups are blocked with —Si(CH₃)₃ groups as shown in FIG. 8. Other end-capping reagents can be used to produce other unreactive molecules such as Hexamethyldisiazane (HMDS), R₃Si(OCH₃), (CH₃)₃Si(OCH₃), R₃SiCl, (CH₃)₃SiCl, R₃OH, CH₃OH, R₃Cl, CH₃Cl, or CH₄. Plasma or other source of energy may be used to activate the production of free radicals from the end capping reagents so that they can react with the active end groups to cap the active end groups. The capped end groups prevent the molecules from cross-linking among each other and prevent increase internal stress in the film and mitigate shrinkage and cracking of the film in subsequent processing.

In one embodiment, after the dielectric film is formed such as shown in FIG. 6, the film is subjected to treatment with an end-capping reagent. Following the end-capping reagent treatment, the dielectric film is cured (e.g., by E-beam curing, UV curing, evaporation, or thermal curing) to allow the pore-forming agent to decompose to generate pores in the dielectric film.

In another embodiment, after the dielectric film is formed such as shown in FIG. 6 and exposed to moisture or the ambient such as shown in FIG. 7, the film is subjected to treatment with an end-capping reagent. The end-capping reagent blocks the active end groups Si—H and/or Si—OH to form the dielectric film shown in FIG. 8. Following the end-capping reagent treatment, the dielectric film is cured (e.g., by E-beam curing, UV curing, evaporation, or thermal curing) to allow the pore-forming agent to decompose to generate pores in the dielectric film.

In yet another embodiment, after the dielectric film is formed such as shown in FIG. 6, the dielectric film is cured (e.g., by E-beam curing, UV curing, or thermal curing) to allow the pore-forming agent to decompose to generate pores in the dielectric film. Immediately following the curing, the dielectric film is treated with an end-capping reagent to block the active end groups from cross-linking to one another.

In yet another embodiment, after the dielectric film is formed as shown in FIG. 6, the dielectric film is cured in the presence of an end-capping reagent to prevent the active end groups from cross-linking to one another. The dielectric film may be exposed or treated with the end-capping reagent immediately prior to curing, during curing, or immediately after curing.

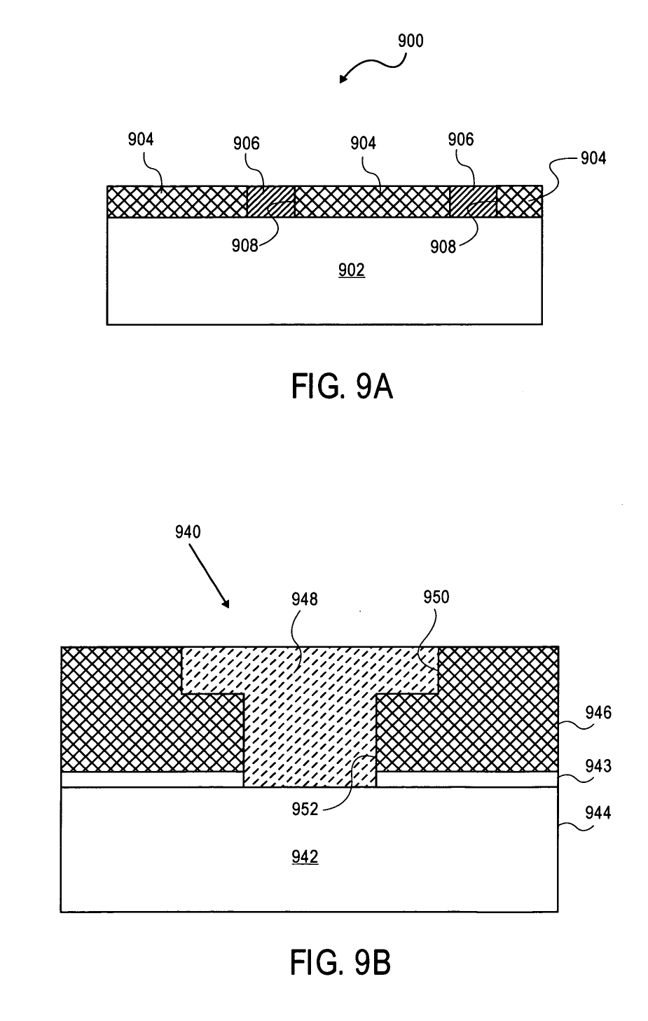

Referring to FIG. 9A, a microelectronic device 900 is illustrated. A substrate 902 is provided, which often is comprised of several active devices (e.g., transistor or capacitor) and/or a layer with metal exposed. The substrate 902 may be a semiconductor wafer (for example, made of silicon, monocrystalline silicon, or polycrystalline silicon) including device regions, other structures such as gates, local interconnects, metal layers, or other active/passive device structures or layers (not shown). A dielectric layer 904 made in according to embodiments of the present invention is formed on top of the substrate 902. The dielectric layer 904 is porous, has a low dielectric constant K (e.g., less than 3, more preferably, less than 2.7 or even more preferably, less than 2.5), and has active end groups (e.g., Si—H or Si—OH) capped by unreactive moiety so that cross-linking among the active end groups is substantially minimized or mitigated. In one embodiment, the dielectric layer 904 is formed to have a porosity of about 45% to about 80%. The pores in the dielectric layer 904 may range from 20-50 Angstroms. The dielectric layer 904 may have a thickness in the range of 100-10000 Angstroms. In one embodiment, vias 908 are created into the dielectric layer 904 using a conventional method to enable electrical interconnection to an active device on or in the substrate 902. Interconnects 906 are then formed on the dielectric layer 904 and into the vias 908 to electrically connect to the particular active device. Although it is not shown, multiple layers of dielectrics 904 and multiple interconnections 906 may be formed on top of each other depending on applications and the microelectronic devices to be formed. It is to be noted that the dielectric layer 904 may be formed directly on the substrate 902 and treated with the end-capping reagent. Then, the vias 908 and interconnections 906 can be formed as shown in FIG. 9A prior to curing to allow the generation of the pores in the dielectric layer 904.

Referring to FIG. 9B, a microelectronic device 940 is illustrated. A substrate 942 is provided, which often is comprised of several active devices (e.g., transistor or capacitor) and/or a layer with metal exposed. The substrate 942 may be a semiconductor wafer (for example, made of silicon, monocrystalline silicon, or polycrystalline silicon) including device regions, other structures such as gates, local interconnects, metal layers, or other active/passive device structures or layers (not shown). In one embodiment, an etch stop layer 943 is also formed on the substrate 942 which can be comprised of numerous materials. The etch stop layer 943 is typically used in a dual-damascene process to form interconnects for a device. In one embodiment, the etch stop layer 943 comprises of silicon nitride or silicon carbide.

Then, a porous interlayer dielectric layer 946 is formed using exemplary embodiments of the present invention. The dielectric layer 946 is disposed on the substrate 942 and on the etch stop layer 943. The dielectric layer 946 is porous, has a low dielectric constant K (e.g., less than 3, more preferably, less than 2.7 or even more preferably, less than 2.5), and has active end groups (e.g., Si—H or Si—OH) capped by unreactive moiety so that cross-linking among the active end groups is substantially minimized or mitigated. In one embodiment, the dielectric layer 946 is formed to have a porosity of about 45% to about 80%. The pores in the dielectric layer 946 may range from 20-50 Angstroms. The dielectric layer 946 may have a thickness in the range of 100-10000 Angstroms.

After forming the dielectric layer 946, vias and trenches, such as via 952 and trench 950 in FIG. 9B, are etched into the dielectric layer 946 and through etch stop 943 using methods known in the art. An exemplary method includes dual damascene. Then, as illustrated in FIG. 9B, interconnects such as interconnect 948 is formed in the via 952 and the trench 950. In one embodiment, the interconnect 948 is a metal conductor which comprises of copper. The metal conductor may also include a copper alloy or some other conductive metal. An ordinary plating process may be used to form metal conductor.

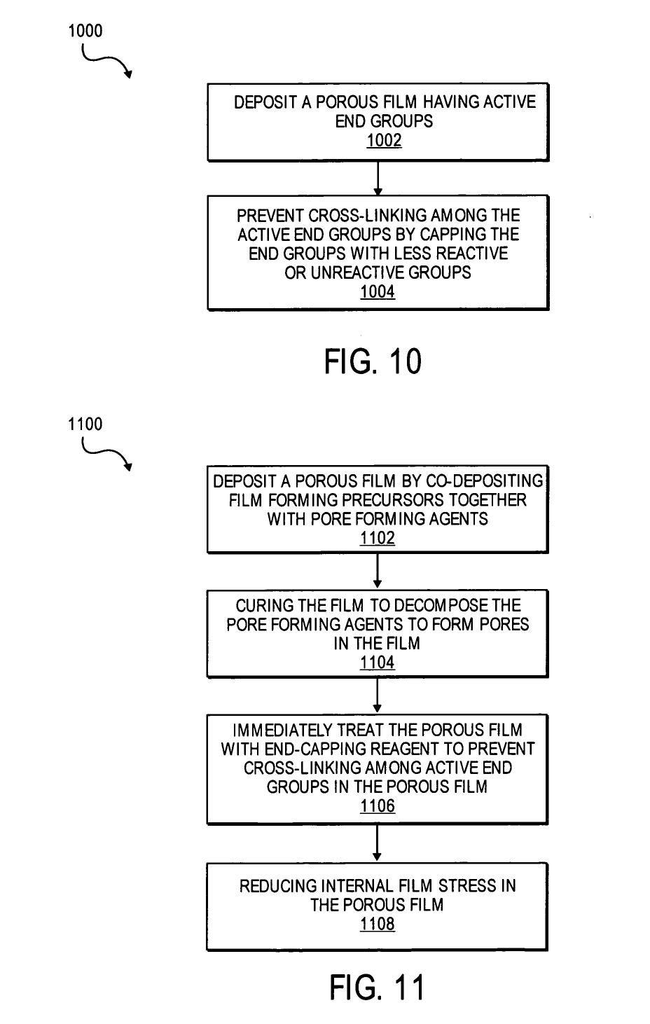

FIG. 10 illustrates an exemplary method 1000 of forming of porous dielectric film. At operation 1002, a dielectric film is deposited, e.g., by Chemical Vapor Deposition, Physical Vapor Deposition, Plasma Enhanced Chemical Vapor Deposition, or Spin-on deposition. The dielectric film comprises active end groups such as Si—H or Si—OH, which are formed as pores are often generated in the dielectric film. At operation 1004, cross-linking among active end groups in the dielectric film is prevented by capping the end groups with less reactive or unreactive groups. To form the porous dielectric film, dielectric material precursors are co-deposited with a pore-forming agent, for example, in a deposition chamber. The pore-forming agent is decomposed to generate pores in the dielectric film. To prevent cross-linking among active end groups, an end-capping reagent is used to treat the dielectric film before, during, or immediately after a curing process. In one embodiment, the capping process also reduces internal film stress in the porous dielectric film.

FIG. 11 illustrates an exemplary method 1100 of forming a porous dielectric film. At operation 1102, the film is deposited by co-depositing film forming precursors together with a pore-forming agent in a deposition chamber. At operation 1104, the film is cured to decompose the pore-forming agent to allow the pores to be generated. At operation 1106, immediately follow the curing process with treating the film with and end-capping reagent to prevent cross-linking among active end groups. At operation 1108, the internal film stress in the porous film is reduced since cross-linking among active end groups is reduced, mitigated, or eliminated.

In an alternative method, just prior to curing the film to decompose the pore-forming agent, the film is exposed to en end-capping reagent. Then, curing follows the end-capping reagent treatment process. In another alternative method, an end-capping reagent is introduced into the curing environment while the film is being cured.

While the invention has been described in terms of several embodiments, those of ordinary skill in the art will recognize that the invention is not limited to the embodiments described. The method and apparatus of the invention, but can be practiced with modification and alteration within the spirit and scope of the appended claims. The description is thus to be regarded as illustrative instead of limiting.

Having disclosed exemplary embodiments, modifications and variations may be made to the disclosed embodiments while remaining within the spirit and scope of the invention as defined by the appended claims.

We claim:

1. A method comprising:
depositing a porous film, said porous film having active end groups; and
preventing cross-linking among said active end groups, said preventing includes capping said end groups with less reactive or unreactive groups.

2. The method of claim 1 wherein depositing said porous film further comprises,
co-depositing precursors for said porous film and pore-forming agents in a deposition device to form pores in said porous film; and
decomposing said pore-forming agents for form pores in said porous film.

3. The method of claim 1 wherein capping said end groups with said less reactive or unreactive groups comprises,
treating said porous film after said depositing with reagents that provide said less reactive or unreactive groups to bond said less reactive or unreactive groups to said active end groups; and
curing said porous film.

4. The method of claim 1 wherein depositing said porous film further comprises co-depositing precursors for said porous film and pore-forming agents in a deposition device to form pores in said porous film; and wherein said preventing cross-linking among said active end groups further comprises treating said porous film after said depositing with reagents that provide said less reactive or unreactive groups to bond said less reactive or unreactive groups to said active end groups and curing said porous film.

5. The method claim 1 wherein the porous film has a porosity in the range of 45% to 80%.

6. The method of claim 1 further comprising:
reducing internal film stress in said porous film.

7. The method of claim 1 wherein said less reactive or unreactive groups are provided from a reagent selected from a group consisting of Hexamethyldisiazane (HMDS), R₃Si(OCH₃), (CH₃)₃Si(OCH₃), R₃SiCl, (CH₃)₃SiCl, R₃OH, CH₃OH, R₃Cl, CH₃Cl, or CH₄.

8. The method of claim 1 wherein said reactive groups include —H, Si—, —OH, Si—H and Si—OH.

9. A method of forming a porous dielectric film comprising:
depositing precursors to form a dielectric film in a deposition chamber;
co-depositing with said precursors pore-forming agents;
forming pores in said dielectric film to form said porous dielectric film;
treating said porous dielectric film with end-capping reagents to bond less reactive or unreactive groups to active end groups in said porous dielectric film said less reactive or unreactive groups preventing cross-linking among said active end groups.

10. The method of claim 9 wherein treating said porous dielectric film with end-capping reagents follows immediately after said porous dielectric film is formed.

11. The method of claim 9 further comprising:
decomposing said pore-forming agents for form pores for said porous dielectric film; and followed said decomposing immediately with treating said porous dielectric film with end-capping reagents.

12. The method claim 9 wherein said porous dielectric film has porosity in the range of 45% to 80%.

13. The method of claim 9 further comprising:
reducing internal film stress in said porous dielectric film.

14. The method of claim 9 wherein said end-capping reagent is selected from a group consisting of Hexamethyldisiazane (HMDS), R₃Si(OCH₃), (CH₃)₃Si(OCH₃), R₃SiCl, (CH₃)₃SiCl, R₃OH, CH₃OH, R₃Cl, CH₃Cl, or CH₄.

15. The method of claim 9 wherein said reactive groups include Si—H and Si—OH.

16. A microelectronic device comprising:
a substrate having microelectronic elements formed thereon;
a porous dielectric film formed on said substrate, said dielectric film having a low-k dielectric constant, said dielectric film having no cross-linking among active end groups present in said dielectric film, the active end groups being capped by less reactive or unreactive end groups; and
one or more conductive interconnects formed on said dielectric film.

17. The microelectronic device of claim 16 wherein said dielectric film has porosity in a range of 45% to 80%.

18. The microelectronic device of claim 16 wherein said low-k dielectric is less than 3.

19. The microelectronic device of claim 16 wherein said dielectric film has active end groups bonded to unreactive end groups to prevent cross-linking among said active end groups.

20. The microelectronic device of claim 19 wherein said unreactive end groups are formed from Hexamethyldisiazane (HMDS), R₃Si(OCH₃), (CH₃)₃Si(OCH₃), R₃SiCl, (CH₃)₃SiCl, R₃OH, CH₃OH, R₃Cl, CH₃Cl, or CH₄.
